(19) United States
(12) Patent Application Publication
(10) Pub. No.: US 2025/0164564 A1
(43) Pub. Date: May 22, 2025

(54) METHOD, DEVICE AND NON-TRANSITORY COMPUTER-READABLE STORAGE MEDIUM FOR ONLINE DIAGNOSIS OF POWER BATTERY VOLTAGE FAULT BASED ON ENTROPY ALGORITHM

(71) Applicant: CHANG'AN UNIVERSITY, Xi'an (CN)

(72) Inventors: Xuan ZHAO, Xi'an (CN); Jian MA, Xi'an (CN); Kai ZHANG, Xi'an (CN); Yisong CHEN, Xi'an (CN); Xiaolei YUAN, Xi'an (CN); Dean MENG, Xi'an (CN)

(21) Appl. No.: 19/031,712

(22) Filed: Jan. 18, 2025

Related U.S. Application Data
(63) Continuation of application No. PCT/CN2024/105738, filed on Jul. 16, 2024.

(30) Foreign Application Priority Data
Aug. 14, 2023 (CN) 202311016786.1

(51) Int. Cl. G01R 31/367; G01R 31/36; G01R 31/396

(52) U.S. Cl. CPC G01R 31/367; G01R 31/3648; G01R 31/396

(57) ABSTRACT

A method for online diagnosis of power battery voltage fault based on entropy algorithm, in which voltage time-series values of individual cells in a battery pack of a to-be-diagnosed vehicle are obtained to construct a first voltage data matrix; the first voltage data matrix is intercepted by a sliding time window to form a second voltage data matrix; voltage values of the second voltage data matrix are subjected to data exclusion and reconstruction to form a third voltage data matrix; Shannon entropy values of cells are calculated; each Shannon entropy value is transformed into an abnormal fluctuation evaluation coefficient of individual cells; whether there is a abnormal cell is determined; if yes, position and occurrence time of the abnormal cell are determined, and an abnormality degree is evaluated; otherwise, the time window is moved downward, and the above steps are repeated for the next iteration.

### CROSS-REFERENCE TO RELATED APPLICATIONS

This application is a continuation of International Patent Application No. PCT/CN2024/105738, filed on Jul. 16, 2024, which claims the benefit of priority from Chinese Patent Application No. 202311016786.1, filed on Aug. 14, 2023. The content of the aforementioned application, including any intervening amendments made thereto, is incorporated herein by reference in its entirety.

### TECHNICAL FIELD

This application relates to battery fault diagnosis, and more particularly to a method, device and non-transitory computer-readable storage medium for online diagnosis of power battery voltage fault based on an entropy algorithm.

### BACKGROUND

With the rapid development of the electric vehicle industry in recent years, safety accidents caused by faults in power batteries have become increasingly frequent. Therefore, fault diagnosis of electric vehicle power batteries is of great importance. The power battery system faults are often caused by over-voltage, under-voltage, short circuits, over-temperature, or poor consistency of one or more cells. These faults are typically reflected in the cell voltage parameter, i.e., inconsistent voltage fluctuation. Therefore, quickly and accurately monitoring and assessing the abnormal voltage fluctuations in individual cells can provide a more comprehensive understanding of the safety of the power battery system. Currently, various entropy-based methods are widely applied in the battery fault diagnosis due to their remarkable effectiveness in evaluating the system disorder level and uncertainty. However, the improvement of the model precision is often accompanied by the decline in the computational efficiency.

Therefore, there is an urgent need to provide an entropy algorithm-based method for online diagnosis of power battery voltage fault.

### SUMMARY

A purpose of the present application is to provide a method for online diagnosis of power battery voltage fault based on an entropy algorithm to solve the above problems in the prior art.

The present application provides a method for online diagnosis of power battery voltage fault based on an entropy algorithm, comprising:
(S100) obtaining a voltage time-series data of each of a plurality of cells in a battery pack of a to-be-diagnosed vehicle to construct a first voltage data matrix A; wherein the first voltage data matrix A is expressed by:

$$A = [ \begin{matrix}{a}_{1 , 1} & {a}_{1 , 2} & … & {a}_{1 , n} \\ {a}_{2 , 1} & {a}_{2 , 2} & … & {a}_{2 , n} \\ ⋮ & ⋮ & {a}_{i , j} & ⋮ \\ {a}_{m , 1} & {a}_{m , 2} & … & {a}_{m , n}\end{matrix} ] ;$$

wherein m is a time-series length; n is the number of the plurality of cells; and a_{i,j} represents a voltage value of a j-th cell in an i-th index; i=1, 2, . . . m; and j=1, 2, . . . n;
(S101) setting a length and a width of a sliding time window; and performing data interception on the first voltage data matrix A by using the sliding time window to form a second voltage data matrix B;
(S102) subjecting voltage values of the second voltage data matrix B to data exclusion and reconstruction based on a data processing method to form a third voltage data matrix D;
(S103) calculating a Shannon entropy value of each of the plurality of cells based on the third voltage data matrix D by using an optimized entropy algorithm;
(S104) transforming the Shannon entropy value into a voltage abnormal fluctuation evaluation coefficient based on an improved Z-score method;
(S105) determining whether there is an abnormal cell among the plurality of cells based on a safety evaluation strategy; if yes, proceeding to step (S106); otherwise, proceeding to step (s107);
(S106) determining a position and an occurrence time of the abnormal cell; and determining an abnormality degree of the abnormal cell to send a corresponding alert to a driver; and
(S107) moving the sliding time window down within the first voltage data matrix A, and repeating steps (S101)-(S105) for a next iteration.

In an embodiment, the length of the sliding time window is k, and the width of the sliding time window is equal to the number of the plurality of cells n; and the second voltage data matrix B is represented by:

$$B = [ \begin{matrix}{b}_{1 , 1} & {b}_{1 , 2} & … & {b}_{1 , n} \\ {b}_{2 , 1} & {b}_{2 , 2} & … & {b}_{2 , n} \\ ⋮ & ⋮ & {b}_{i , j} & ⋮ \\ {b}_{k , 1} & {b}_{k , 2} & … & {b}_{k , n}\end{matrix} ] ;$$

wherein b_{i,j} represents the voltage value of the j-th cell at the i-th index; i=1, 2, . . . k; and j=1, 2, . . . n

In an embodiment, the step (S102) comprises:
(S200) monitoring a voltage difference between neighboring data sampling points for each of the plurality of cells to establish a voltage difference matrix C; wherein the voltage difference matrix C is represented by:

$$C = [ \begin{matrix}{c}_{1 , 1} & {c}_{1 , 2} & … & {c}_{1 , n} \\ {c}_{2 , 1} & {c}_{2 , 2} & … & {c}_{2 , n} \\ ⋮ & ⋮ & {c}_{i , j} & ⋮ \\ {c}_{k - 1 , 1} & {c}_{k - 1 , 2} & … & {c}_{k - 1 , n}\end{matrix} ] ;$$

wherein c_{i,j} represents a voltage difference of the j-th cell between the i-th index and an (i+1)-th index; i=1, 2, . . . , k−1; and j=1, 2, . . . , n;
(S201) for each of the plurality of cells, identifying data locations in the voltage difference matrix C where voltage differences are not greater than 0.001V, and locking row indices for more than k/10 consecutive data points;
(S202) removing data fragments corresponding to the row indices identified in step (S201) from the second voltage data matrix B; and
(S203) sequentially splicing remaining data in the second voltage data matrix B to form the third voltage data matrix D, wherein a value of a spliced point is an average of values of an immediately preceding row and an immediately following row;
the third voltage data matrix D is represented by:

$$D = [ \begin{matrix}{d}_{1 , 1} & {d}_{1 , 2} & … & {d}_{1 , n} \\ {d}_{2 , 1} & {d}_{2 , 2} & … & {d}_{2 , n} \\ ⋮ & ⋮ & {d}_{i , j} & ⋮ \\ {d}_{e , 1} & {d}_{e , 2} & … & {d}_{e , n}\end{matrix} ] ;$$

wherein d_{i,j} represents a voltage of the j-th cell at the i-th index, and e≤k.

In an embodiment, the step (S103) comprises:
(S300) finding a maximum value dₘₐₓ and a minimum value dₘᵢₙ of the third voltage data matrix D; wherein the maximum value dₘₐₓ and the minimum value dₘᵢₙ are represented by:

$$\{ \begin{matrix}{d}_{min} = min \{ {d}_{i , j} \vert i = 1 , 2 , … , e ; j = 1 , 2 , … , n \} \\ {d}_{max} = max \{ {d}_{i , j} \vert i = 1 , 2 , … , e ; j = 1 , 2 , … , n \}\end{matrix} ;$$

(S301) dividing a range formed by the maximum value dₘₐₓ and the minimum value dₘᵢₙ into/intervals, each represented by:

$$( {d}_{min} + ( L - 1 ) \frac{{d}_{max} - {d}_{min}}{l} , {d}_{min} + L \frac{{d}_{max} - {d}_{min}}{l} ) ;$$

wherein L=1, 2, 3, . . . 1;
(S302) calculating the number of voltage values of each of the plurality of cells in the third voltage data matrix D respectively falling into each of the/intervals to obtain a frequency matrix F, represented by:

$$F = [ \begin{matrix}{f}_{1 , 1} & {f}_{1 , 2} & … & {f}_{1 , n} \\ {f}_{2 , 1} & {f}_{2 , 2} & … & {f}_{2 , n} \\ ⋮ & ⋮ & {f}_{i , j} & ⋮ \\ {f}_{l , 1} & {f}_{l , 2} & … & {f}_{l , n}\end{matrix} ] ;$$

wherein f_{i,j} represents the number of voltage values of the j-th cell in the third voltage data matrix D that falls into an i-th interval;
(S303) dividing each value in the frequency matrix F by a sum of values in a corresponding column of the frequency matrix F to obtain a probability matrix P, represented by:

$$P = [ \begin{matrix}{p}_{1 , 1} & {p}_{1 , 2} & … & {p}_{1 , n} \\ {p}_{2 , 1} & {p}_{2 , 2} & … & {p}_{2 , n} \\ ⋮ & ⋮ & {p}_{i , j} & ⋮ \\ {p}_{l , 1} & {p}_{l , 2} & … & {p}_{l , n}\end{matrix} ] ;$$

wherein

$${p}_{i , j} = \frac{{f}_{i , j}}{{\sum }_{i = 1}^{l} {f}_{i , j}} ,$$

representing a probability that the voltage values of the j-th cell in the third voltage data matrix D fall into the i-th interval; and
(S304) calculating the Shannon entropy value of each of the plurality of cells based on the second voltage data matrix B to obtain a first Shannon entropy sequence H(B); wherein the first Shannon entropy sequence H(B) is expressed by:

$$H ( B ) = [ {H}_{1} , {H}_{2} , … , {H}_{j} , … , {H}_{n} ] ;$$

$$wherein {H}_{j} = - {\sum }_{i = 1}^{l} {p}_{i , j} log {p}_{i , j} ,$$

representing a Shannon entropy value of the j-th cell calculated based on the second voltage data matrix B.

In an embodiment, the step (S104) comprises:
(S400) obtaining the first Shannon entropy sequence H(B);
(S401) calculating a mean value μ_{H} of Shannon entropy values of the plurality of cells in the first Shannon entropy sequence;
(S402) excluding values exceeding 2*μH from the first Shannon entropy sequence H(B) to form a second Shannon entropy sequence H(B)′; and
calculating a mean value and a standard deviation of Shannon entropy values in the second Shannon entropy sequence H(B)′ respectively according to the following equations:

$${μ}_{{H}^{′}} = \frac{1}{g} {\sum }_{j = 1}^{g} {H}_{j} ; and$$

$${σ}_{{H}^{′}} = \sqrt{\frac{1}{g} {\sum }_{{j = 1}^{}}^{g} {( {H}_{j} - {μ}_{{H}^{′}} )}^{2}} ;$$

calculating a median Hₘₑ of the Shannon entropy values of the plurality of cells in the second Shannon entropy sequence; and
(S404) normalizing the Shannon entropy values of the plurality of cells in the second Shannon entropy sequence H(B) to obtain the voltage abnormal fluctuation evaluation coefficient of the plurality of cells, expressed by:

$${AF}_{j} = \frac{{H}_{{j}^{′}} - {H}_{me}}{{σ}_{{H}^{′}}} ;$$

wherein Hⱼ′ represents a Shannon entropy value of the j-th cell in the second Shannon entropy sequence; and σ_{H}′ represents the standard deviation of the second Shannon entropy sequence.

In an embodiment, the step of determining whether a abnormal cell among the plurality of cells exists based on a safety evaluation strategy comprises:
(S500) determining whether there is a cell among the plurality of cells whose voltage abnormal fluctuation evaluation coefficient absolute value is greater than 3.5, wherein the cell whose voltage abnormal fluctuation evaluation coefficient absolute value is greater than 3.5 is identified as the abnormal cell;
(S501) if not, proceeding to step (S502); and if yes, proceeding to step (S503);
(S502) moving the sliding time window down by one row within the first voltage data matrix A and repeating steps (S101)-(S105) for the next iteration;
(S503) determining whether the voltage abnormal fluctuation evaluation coefficient absolute value is larger than 4; if yes, proceeding to step (S505), otherwise, proceeding to step (S504);
(S504) sending a secondary fault warning; calculating a duration of a secondary fault; determining whether the duration of the secondary fault exceeds a preset threshold; if yes, proceeding to step (S505), otherwise, returning to step (S502);
(S505) sending a primary fault warning to the driver, and checking the to-be-diagnosed vehicle.

The present application further provides a device for online fault diagnosis of power battery voltage based on entropy algorithm, comprising:
a memory configured to store a computer program; and
a processor;
wherein the processor is configured to execute the computer program to implement the method for online diagnosis of power battery voltage fault based on entropy algorithm.

The present application further provides a non-transitory computer-readable storage medium, wherein the non-transitory computer-readable storage medium stores a computer program; and the computer program is configured to be executed by a processor to implement the method for online diagnosis of power battery voltage fault based on entropy algorithm.

This application at least has the following beneficial effects.

The existing method typically adopts entropy calculations based on intervals and probabilities, but this method is sensitive to changes in the voltage data intervals. The size of Shannon entropy calculated by this method is susceptible to long-duration voltage data segments without fluctuations, leading to a high misdiagnosis rate. To address this, the method provided herein provides an additional data processing step that involves excluding and reconstructing the raw data. The data processing principle ensures that fault data without abnormal fluctuations is excluded, while also removing data segments prone to misdiagnosis, remarkably improving fault diagnosis accuracy.

Furthermore, in the existing Z-score methods, the mean value and standard deviation calculations are susceptible to extreme values. To further improve the precision of abnormal detection for cells, the method provided herein replaces the mean value by the median during the normalization process of Shannon entropy and removes outliers before calculating the standard deviation. The method provided herein further reduces the misdiagnosis rate.

The method provided herein also employs the principle of the sliding time window, using the voltage data within the sliding window to locate the position and occurrence time of the faculty cell. This reduces the computational load and enables real-time application, distinguishing this method from existing fault diagnosis methods that calculate the data over their entire lifecycle.

### BRIEF DESCRIPTION OF THE DRAWINGS

The present disclosure will be described in detail below with reference to the accompanying drawings.

FIG. 1 is a flowchart of the method for online fault diagnosis of power battery voltage based on an entropy algorithm according to one embodiment of the present disclosure;

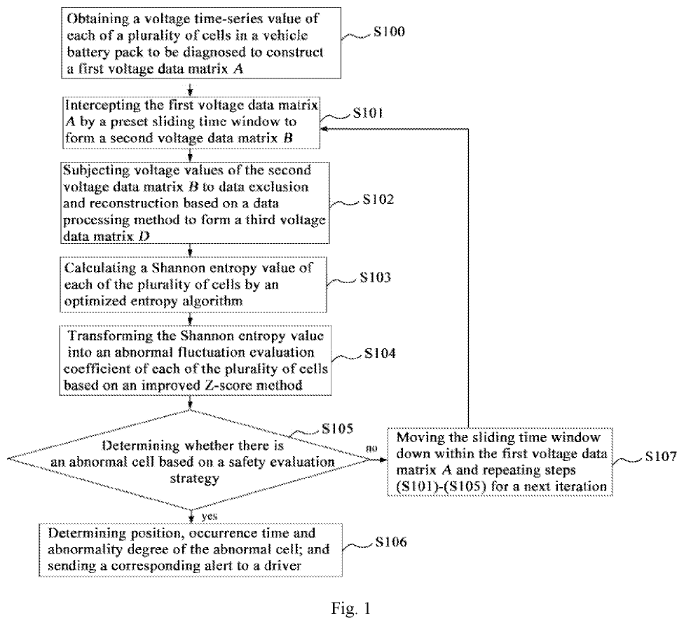

FIG. 2 is a flowchart of the data exclusion and reconstruction according to one embodiment of the present disclosure;

FIG. 3 is a flowchart of the optimized entropy algorithm according to one embodiment of the present disclosure;

FIG. 4 is a flowchart of the improved Z-score method according to one embodiment of the present disclosure; and

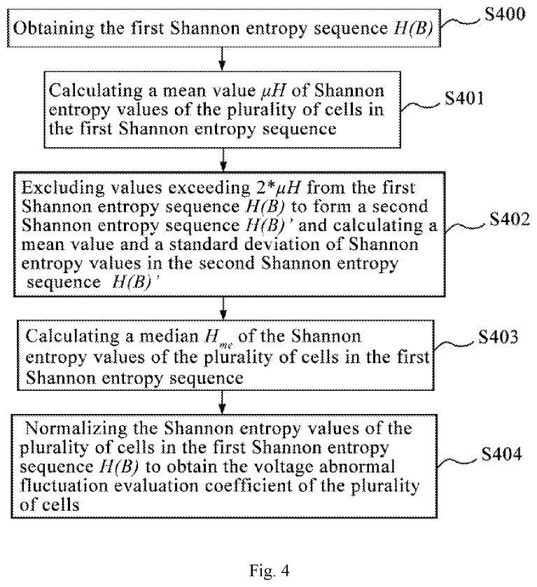

FIG. 5 is a flowchart of the diagnosis and handling of the abnormal cell according to one embodiment of the present disclosure.

### DETAILED DESCRIPTION OF EMBODIMENTS

The technical solutions of this application are described in detail below with reference to the accompanying drawings and specific embodiments. It should be understood that the embodiments of this application and the specific features within the embodiments are detailed descriptions of the technical solutions of this application and are not intended to limit the technical solutions of this application. Where there is no conflict, the embodiments of this application and the technical features within the embodiments may be combined with one another.

A method for online fault diagnosis of power battery voltage based on an entropy algorithm provided herein includes the following steps.

(S100) A voltage time-series data of each of a plurality of cells in a battery pack of a to-be-diagnosed vehicle is obtained to construct a first voltage data matrix A; where the first voltage data matrix A is expressed by:

$$A = [ \begin{matrix}{a}_{1 , 1} & {a}_{1 , 2} & L & {a}_{1 , n} \\ {a}_{2 , 1} & {a}_{2 , 2} & L & {a}_{2 , n} \\ M & M & {a}_{i , j} & M \\ {a}_{m , 1} & {a}_{m , 2} & L & {a}_{m , n}\end{matrix} ] ;$$

In the above formula, m is a time-series length; n is the number of the plurality of cells; and a_{i,j} represents a voltage of a j-th cell in an i-th index; i=1, 2, . . . m; and j=1, 2, . . . n.

(S101) A length and a width of a sliding time window are set. Data interception on the first voltage data matrix A is performed by using the sliding time window to form a second voltage data matrix B.

(S102) Voltage values of the second voltage data matrix B is subjected to data exclusion and reconstruction based on a data processing method to form a third voltage data matrix D.

(S103) A Shannon entropy value of each of the plurality of cells is calculated based on the third voltage data matrix D by using an optimized entropy algorithm.

(S104) The Shannon entropy value is transformed into a voltage abnormal fluctuation evaluation coefficient based on an improved Z-score method.

(S105) Whether there is an abnormal cell among the plurality of cells is determined based on a safety evaluation strategy. If yes, step (S106) is performed; otherwise, step (S107) is performed.

(S106) A position and an occurrence time of the abnormal cell are determined. An abnormality degree of the abnormal cell is determined to send a corresponding alert to a driver.

(S107) The sliding time window down is moved down within the first voltage data matrix A. Steps (S101)-(S105) are repeated for a next iteration.

In the step (S101), the length of the sliding time window is set as k and the width of the sliding time window is equal to the number of the plurality of cells n. The second voltage data matrix B is represented by:

$$B = [ \begin{matrix}{b}_{1 , 1} & {b}_{1 , 2} & L & {b}_{1 , n} \\ {b}_{2 , 1} & {b}_{2 , 2} & L & {b}_{2 , n} \\ M & M & {b}_{i , j} & M \\ {b}_{k , 1} & {b}_{k , 2} & L & {b}_{k , n}\end{matrix} ] .$$

In the above formula, b_{i,j} represents the voltage value of the j-th cell at the i-th index; i=1, 2, . . . k; and j=1, 2, . . . n.

The step (S102) includes the following sub-steps.

(S200) A voltage difference between neighboring data sampling points for each of the plurality of cells is monitored to establish a voltage difference matrix C.

The voltage difference matrix C is represented by:

$$C = [ \begin{matrix}{c}_{1 , 1} & {c}_{1 , 2} & L & {c}_{1 , n} \\ {c}_{2 , 1} & {c}_{2 , 2} & L & {c}_{2 , n} \\ M & M & {c}_{i , j} & M \\ {c}_{k - 1 , 1} & {c}_{k - 1 , 2} & L & {c}_{k - 1 , n}\end{matrix} ] .$$

In the above formula, c_{i,j} represents a voltage difference of the j-th cell between the i-th index and an (i+1)-th index; i=1, 2, . . . , k−1; and j=1, 2,., n.

(S201) For each of the plurality of cells, data locations in the voltage difference matrix C where voltage differences are not greater than 0.001V are identified, and row indices for more than k/10 consecutive data points are locked.

(S202) Data fragments corresponding to the row indices identified in step (S201) are removed from the second voltage data matrix B.

(S203) Remaining data in the second voltage data matrix B is sequentially spliced to form the third voltage data matrix D, where a value of a spliced point is an average of values of an immediately preceding row and an immediately following row. The third voltage data matrix D is represented by:

$$D = [ \begin{matrix}{d}_{1 , 1} & {d}_{1 , 2} & L & {d}_{1 , n} \\ {d}_{2 , 1} & {d}_{2 , 2} & L & {d}_{2 , n} \\ M & M & {d}_{i , j} & M \\ {d}_{e , 1} & {d}_{e , 2} & L & {d}_{e , n}\end{matrix} ] .$$

In the above formula, d_{i,j} represents a voltage of the j-th cell at the i-th index, and e≤k.

Step (S103) includes the following sub-steps.

(S300) A maximum value dₘₐₓ and a minimum value dₘᵢₙ of the third voltage data matrix D are found. The maximum value dₘₐₓ and the minimum value dₘᵢₙ are represented by:

$$\{ \begin{matrix}{d}_{min} = min \{ {d}_{i , j} \vert i = 1 , 2 , L , e ; j = 1 , 2 , L , n \} \\ {d}_{max} = max \{ {d}_{i , j} \vert i = 1 , 2 , L , e ; j = 1 , 2 , L , n \}\end{matrix} .$$

(S301) A range formed by the maximum value dₘₐₓ and the minimum value dₘᵢₙ is divided into/intervals. Each of/intervals is represented by:

$$( {d}_{min} + ( L - 1 ) \frac{{d}_{max} - {d}_{min}}{l} , {d}_{min} + L \frac{{d}_{max} - {d}_{min}}{l} ) .$$

In the above formula, L=1, 2, 3, . . . . I.

(S302) The number of voltage values of each of the plurality of cells in the third voltage data matrix D respectively falling into each of the/intervals is calculated to obtain a frequency matrix F. The frequency matrix F is represented by:

$$F = [ \begin{matrix}{f}_{1 , 1} & {f}_{1 , 2} & L & {f}_{1 , n} \\ {f}_{2 , 1} & {f}_{2 , 2} & L & {f}_{2 , n} \\ M & M & {f}_{i , j} & M \\ {f}_{l , 1} & {f}_{l , 2} & L & {f}_{l , n}\end{matrix} ] .$$

In the above formula, f_{i,j} represents the number of voltage values of the j-th cell in the third voltage data matrix D that falls into an i-th interval.

(S303) Each value in the frequency matrix F is divided by a sum of values in a corresponding column of the frequency matrix F to obtain a probability matrix P, represented by:

$$P = [ \begin{matrix}{p}_{1 , 1} & {p}_{1 , 2} & L & {p}_{1 , n} \\ {p}_{2 , 1} & {p}_{2 , 2} & L & {p}_{2 , n} \\ M & M & {p}_{i , j} & M \\ {p}_{l , 1} & {p}_{l , 2} & L & {p}_{l , n}\end{matrix} ] .$$

In the above formula,

$${p}_{ij} = \frac{{f}_{i , j}}{{\sum }_{i = 1}^{l} {f}_{i , j}} ,$$

representing a probability that the voltage values of the j-th cell in the third voltage data matrix D fall into the i-th interval.

(S304) The Shannon entropy value of each of the plurality of cells is calculated based on the second voltage data matrix B to obtain a first Shannon entropy sequence H(B). The first Shannon entropy sequence H(B) is expressed by:

H(B)=[H₁,H₂,L,Hⱼ,L,Hₙ].

In the above formula,

$${H}_{j} = - {\sum }_{i = 1}^{l} {p}_{i , j} log {p}_{i , j} ,$$

representing a Shannon entropy value of the j-th cell calculated based on the second voltage data matrix B.

The step (S104) includes the following steps.

(S400) The first Shannon entropy sequence H(B) is obtained.

(S401) A mean value μ_{H} of Shannon entropy values of the plurality of cells in the first Shannon entropy sequence is calculated.

(S402) Values exceeding 2*μH are excluded from the first Shannon entropy sequence H(B) to form a second Shannon entropy sequence H(B)′. A mean value and a standard deviation of Shannon entropy values in the second Shannon entropy sequence H(B)′ are calculated. The mean value of the Shannon entropy values of the second Shannon entropy sequence is represented by:

$${μ}_{{H}^{′}} = \frac{1}{g} {\sum }_{j = 1}^{g} {H}_{j} .$$

The standard deviation of the Shannon entropy values of the second Shannon entropy sequence is represented by:

$${σ}_{{H}^{′}} = \sqrt{\frac{1}{g} {\sum }_{j = 1}^{g} {( {H}_{j} - {μ}_{{H}^{′}} )}^{2}} .$$

(S403) A median Hₘₑ of the Shannon entropy values of the plurality of cells in the second Shannon entropy sequence is calculated.

(S404) The Shannon entropy values of the plurality of cells in the second Shannon entropy sequence H(B)′ are normalized to obtain the voltage abnormal fluctuation evaluation coefficient of the plurality of cells, expressed by:

$${AF}_{j} = \frac{{H}_{{j}^{′}} - {H}_{me}}{{σ}_{{H}^{′}}} .$$

In the above formula, Hⱼ′ represents a Shannon entropy value of the j-th cell in the second Shannon entropy sequence; and σ_{H}′ represents the standard deviation of the second Shannon entropy sequence.

The safety evaluation strategy is performed through the following steps.

(S500) Whether there is a cell among the plurality of cells whose voltage abnormal fluctuation evaluation coefficient absolute value is greater than 3.5 is determined. The cell whose voltage abnormal fluctuation evaluation coefficient absolute value is greater than 3.5 is identified as the abnormal cell.

(S501) If not, step (S502) is proceeded. If yes, step (S503) is proceeded.

(S502) The sliding time window is moved down by one row within the first voltage data matrix A and steps (S101)-(S105) are repeated for the next iteration.

(S503) Whether the voltage abnormal fluctuation evaluation coefficient absolute value is larger than 4 is determined. If yes, step (S505) is proceeded. Otherwise, step (S504) is proceeded.

(S504) A secondary fault warning is sent. A duration of a secondary fault is calculated. Whether the duration of the secondary fault exceeds a preset threshold is determined. If yes, step (S505) is proceeded with. Otherwise, step (S502) is returned.

(S505) A primary fault warning is sent to the driver, the to-be-diagnosed vehicle is checked.

Specifically, as an example, consider a vehicle battery pack with 95 cells and 200 sampling data points. Based on this data, the voltage-time series matrix A for all cells is constructed as follows:

$$A = [ \begin{matrix}{a}_{1 , 1} & {a}_{1 , 2} & L & {a}_{1 , 95} \\ {a}_{2 , 1} & {a}_{2 , 2} & L & {a}_{2 , 95} \\ M & M & {a}_{i , j} & M \\ {a}_{200 , 1} & {a}_{200 , 2} & L & {a}_{200 , 95}\end{matrix} ] .$$

In the above formula, a_{i,j} represents a voltage value of the j-th cell at the i-th index; i=1, 2, . . . 200; and j=1,2, . . . 95.

In the step (S101), the length of the sliding time window is 100 and the width of the sliding time window is 95. Using the sliding time window, the voltage-time series matrix A is intercepted. The voltage data matrix B segmented for first iteration is expressed by:

$$B = [ \begin{matrix}{a}_{1 , 1} & {a}_{1 , 2} & L & {a}_{1 , 95} \\ {a}_{2 , 1} & {a}_{2 , 2} & L & {a}_{2 , 95} \\ M & M & M & M \\ {a}_{100 , 1} & {a}_{100 , 2} & L & {a}_{100 , 95}\end{matrix} ] .$$

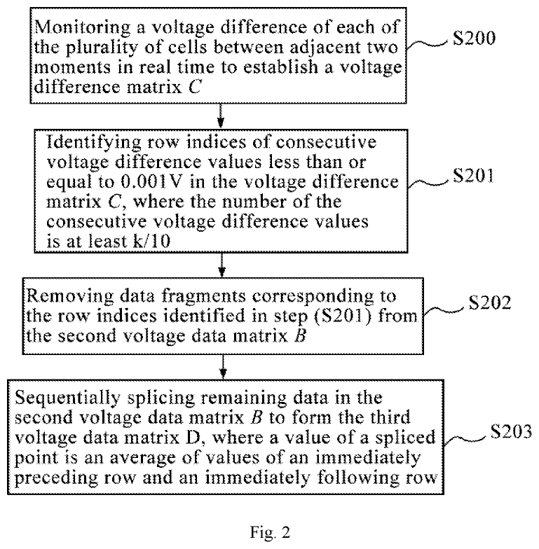

Based on the voltage data matrix B, the step (S102) is executed according to the flowchart shown in FIG. 2, with the specific data processing principles as follows.

In the step (S200), the voltage differences between neighboring data sampling points for each cell are monitored, and the voltage difference matrix C for each cell in the voltage data matrix B is established. The voltage difference matrix C is represented by:

$$C = [ \begin{matrix}{a}_{2 , 1} - {a}_{1 , 1} & {a}_{2 , 2} - {a}_{1 , 2} & L & {a}_{2 , 95} - {a}_{1 , 95} \\ {a}_{3 , 1} - {a}_{2 , 1} & {a}_{3 , 2} - {a}_{2 , 2} & L & {a}_{3 , 95} - {a}_{2 , 95} \\ M & M & M & M \\ {a}_{100 , 1} - {a}_{99 , 1} & {a}_{100 , 2} - {a}_{99 , 2} & L & {a}_{100 , 95} - {a}_{99 , 95}\end{matrix} ] .$$

In the step (S201), for each of the plurality of cells, data locations in the voltage difference matrix C where voltage differences are not greater than 0.001V are identified, and row indices for more than 10 consecutive data points are locked.

In the step (S202), the data fragments corresponding to the row indices identified in step S201 are removed from the voltage data matrix B.

In the step (S203), the remaining data in the voltage data matrix B is sequentially spliced, and the value of the spliced point is an average of values of an immediately preceding row and an immediately following row.

$$D = [ \begin{matrix}{d}_{1 , 1} & {d}_{1 , 2} & L & {d}_{1 , 95} \\ {d}_{2 , 1} & {d}_{2 , 2} & L & {d}_{2 , 95} \\ M & M & M & M \\ {d}_{e , 1} & {d}_{e , 2} & L & {d}_{e , 95}\end{matrix} ] .$$

In the above formula, d_{i,j} represents a voltage of the j-th cell at the i-th index, and e≤k.

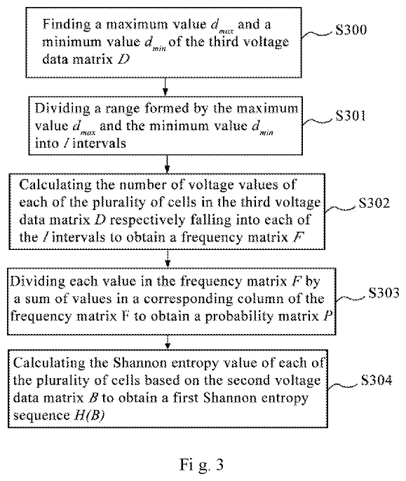

The step (S103) (the optimized entropy algorithm) is executed as shown in FIG. 3. The step (S103) includes the following steps.

In the step (S300), a maximum value dₘₐₓ and a minimum value dₘᵢₙ of the voltage data matrix D are found. The maximum value dₘₐₓ and the minimum value dₘᵢₙ are represented by:

$$\{ \begin{matrix}{d}_{min} = min \{ {d}_{i , j} \vert i = 1 , 2 , L , e ; j = 1 , 2 , L , 95 \} \\ {d}_{max} = max \{ {d}_{i , j} \vert i = 1 , 2 , L , e ; j = 1 , 2 , L , 95 \}\end{matrix} .$$

In the step (S301), the interval (dₘᵢₙ, dₘₐₓ) is divided into 10 intervals. The 10 intervals are each represented by:

$$( {d}_{min} + ( L - 1 ) \frac{{d}_{max} - {d}_{min}}{10} , {d}_{min} + L \frac{{d}_{max} - {d}_{min}}{10} ) .$$

In the above formula, L=1, 2, . . . , 10.

In the step (S302), the number of voltage values for each cell in the voltage data matrix D respectively falling into each of the 10 intervals is calculated to obtain a frequency matrix F. The frequency matrix F is represented by:

$$F = [ \begin{matrix}{f}_{1 , 1} & {f}_{1 , 2} & L & {f}_{1 , 95} \\ {f}_{2 , 1} & {f}_{2 , 2} & L & {f}_{2 , 95} \\ M & M & {f}_{i , j} & M \\ {f}_{10 , 1} & {f}_{10 , 2} & L & {f}_{10 , 95}\end{matrix} ] .$$

In the above formula, f_{i,j} represents the number of voltage values of the j-th cell in the voltage data matrix D that falls into the intervals

$${}^{} {}^{{″}_{}} {( {d}_{min} + ( i - 1 ) \frac{{d}_{max} - {d}_{min}}{10} , {d}_{min} + i \frac{{d}_{max} - {d}_{min}}{10} )}^{″}$$

In the step (S303), the probability matrix P is calculated based on matrix F. The probability matrix P is represented by:

$$P = [ \begin{matrix}{p}_{1 , 1} & {p}_{1 , 2} & L & {p}_{1 , 95} \\ {p}_{2 , 1} & {p}_{2 , 2} & L & {p}_{2 , 95} \\ M & M & {p}_{i , j} & M \\ {p}_{10 , 1} & {p}_{10 , 2} & L & {p}_{10 , 95}\end{matrix} ] .$$

In the above formula,

$${p}_{i , j} = \frac{{f}_{i , j}}{{\sum }_{i = 1}^{l} {f}_{i , j}} ;$$

represents a probability that the voltage values of the j-th cell in the voltage data matrix D fall into the i-th interval.

In the step (S304), a Shannon entropy sequence H(B) is obtained based on the voltage data matrix B. The Shannon entropy sequence H(B) is expressed by:

H(B)=[H₁,H₂,L,Hⱼ,L,H₉₅].

In the above formula,

$${H}_{j} = - {\sum }_{i = 1}^{l} {p}_{i , j} log {p}_{i , j} ;$$

and Hⱼ represents a Shannon entropy value of the j-th cell calculated based on the second voltage data matrix B.

The step (S104) (the improved Z-score method) is executed as shown in FIG. 3. The step (S104) includes the following steps.

In the step (S401), the mean value μ_{H} of the Shannon entropy sequence H(B) is calculated. The mean value of the Shannon entropy sequence is expressed by:

$${μ}_{{}_{H}} = \frac{1}{95} {\sum }_{j = 1}^{95} {H}_{j} .$$

In the step (S402), a Shannon entropy value in the first Shannon entropy sequence H(B) that exceeds a value of 2*μH is excluded to form a second Shannon entropy sequence H(B)′. H(B)′=[H₁, H₂,L, H_{g}]. A mean value and a standard deviation of Shannon entropy values of H(B)′ are calculated. The mean value of the Shannon entropy values of H(B)′ is represented by:

$${{{μ}_{{H}^{′}}}_{}}_{} = \frac{1}{g} {\sum }_{j = 1}^{g} {H}_{j} .$$

The standard deviation of the Shannon entropy values of H(B) is represented by:

$${{σ}_{{H}^{′}}}_{} = \sqrt{\frac{1}{g} {\sum }_{{j = 1}^{}}^{g} {( {H}_{j} - {μ}_{{H}^{′}} )}^{2}} .$$

In the step (S403), a median Hₘₑ of the Shannon entropy value of the Shannon entropy sequence in the second Shannon entropy sequence is calculated.

In the step (S404), the Shannon entropy values in the sliding time window based on the Z-score theory are normalized to obtain the voltage abnormal fluctuation evaluation coefficient AF for each cell. The voltage abnormal fluctuation evaluation coefficient AF is represented by:

$$A {F}_{j} = \frac{{H}_{{j}^{′}} - {H}_{m e}}{{σ}_{{H}^{′}}} .$$

In the above formula, Hⱼ′ represents a Shannon entropy value of the j-th cell in the second Shannon entropy sequence; and σ_{H}′ represents the standard deviation of the second Shannon entropy sequence.

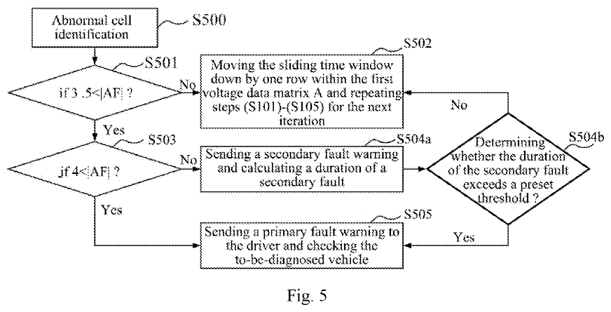

Finally, steps (S105), (S106) and (S107) are executed according to the process shown in FIG. 5. The safety evaluation strategy to detect the battery voltage fault includes sub-steps as follows.

In the step (S500), based on a large amount of real fault and normal vehicle data analysis and verification, cell with 3.5<|AF| is identified as having voltage abnormal fluctuations, indicating the abnormal cell.

In step (S501), if 3.5<|AF|, the system will proceed to step (S503). If |AF|≤3.5, no voltage abnormal fluctuations are detected in the cell and step (S502) is proceeded.

In the step (S502), the sliding time window is moved down one row within the first voltage data matrix A and then steps (S101)-(S105) are repeated for the second iteration. The matrix B in the second iteration is represented by:

$$B = [ \begin{matrix}{a}_{2 , 1} & {a}_{2 , 2} & L & {a}_{2 , 95} \\ {a}_{3 , 1} & {a}_{3 , 2} & L & {a}_{3 , 95} \\ M & M & M & M \\ {a}_{101 , 1} & {a}_{101 , 2} & L & {a}_{101 , 95}\end{matrix} ] .$$

In the step (S503), whether the absolute value of the voltage abnormal fluctuation evaluation coefficient of the abnormal cell is larger than 4 is determined. If yes, step (S505) is proceeded; otherwise, step (S504) is proceeded.

The step (S504) has step (S504a) and step (S504b). In the step (S504a), a secondary fault warning is sent and a duration of a secondary fault is calculated. In the step (S504b), whether the duration of the secondary fault exceeds a preset threshold is determined; if yes, step (S505) is proceeded, otherwise, step (S502) is returned.

In the step (S505), a primary fault warning is sent to the driver, and the to-be-diagnosed vehicle is checked.

The above process exemplifies the complete calculation process for a single data interception using the sliding time window. In the implementation of this present disclosure, the method for online diagnosis of power battery voltage faults based on the entropy algorithm can continuously repeat the above steps for iterative calculations, enabling real-time and accurate assessment of voltage abnormal fluctuation.

Based on the same inventive concept as the aforementioned embodiment of the method for online diagnosis of power battery voltage faults using the entropy algorithm, the present disclosure also provides a device for online diagnosis of power battery voltage faults based on the entropy algorithm. This device includes a memory configured to store a computer program; and a processor. The processor is configured to execute the computer program to implement the steps of:

(S100) A voltage time-series data of each of a plurality of cells in a battery pack of a to-be-diagnosed vehicle is obtained to construct a first voltage data matrix A; where the first voltage data matrix A is expressed by:

$$A = [ \begin{matrix}{a}_{1 , 1} & {a}_{1 , 2} & L & {a}_{1 , n} \\ {a}_{2 , 1} & {a}_{2 , 2} & L & {a}_{2 , n} \\ M & M & {a}_{i , j} & M \\ {a}_{m , 1} & {a}_{m , 2} & L & {a}_{m , n}\end{matrix} ] .$$

In the above formula, m is a time-series length; n is the number of the plurality of cells; and a_{i,j} represents a voltage of a j-th cell in an i-th index; i=1, 2, . . . m; and j=1, 2, . . . n.

(S101) A length and a width of a sliding time window are set. Data interception on the first voltage data matrix A is performed by using the sliding time window to form a second voltage data matrix B.

(S102) Voltage values of the second voltage data matrix B is subjected to data exclusion and reconstruction based on a data processing method to form a third voltage data matrix D.

(S103) A Shannon entropy value of each of the plurality of cells is calculated based on the third voltage data matrix D by using an optimized entropy algorithm;.

(S104) The Shannon entropy value is transformed into a voltage abnormal fluctuation evaluation coefficient based on an improved Z-score method.

(S105) Whether there is an abnormal cell among the plurality of cells is determined based on a safety evaluation strategy. If yes, step (S106) is proceeded; otherwise, step (S107) is proceeded.

(S106) A position and an occurrence time of the abnormal cell are determined. An abnormality degree of the abnormal cell is determined to send a corresponding alert to a driver.

(S107) The sliding time window down is moved down within the first voltage data matrix A. Steps (S101)-(S105) are repeated for a next iteration.

Based on the same inventive concept as the aforementioned embodiment of the method for online diagnosis of power battery voltage faults using the entropy algorithm, the present disclosure also provides a non-transitory computer-readable storage medium. The non-transitory computer-readable storage medium stores an computer program; and the computer program is configured to be executed by a processor to implement the steps of:

(S100) A voltage time-series data of each of a plurality of cells in a battery pack of a to-be-diagnosed vehicle is obtained to construct a first voltage data matrix A; where the first voltage data matrix A is expressed by:

$$A = [ \begin{matrix}{a}_{1 , 1} & {a}_{1 , 2} & L & {a}_{1 , n} \\ {a}_{2 , 1} & {a}_{2 , 2} & L & {a}_{2 , n} \\ M & M & {a}_{i , j} & M \\ {a}_{m , 1} & {a}_{m , 2} & L & {a}_{m , n}\end{matrix} ] .$$

In the above formula, m is a time-series length; n is the number of the plurality of cells; and a_{i,j} represents a voltage of a j-th cell in an i-th index; i=1, 2, . . . m; and j=1, 2, . . . n.

(S101) A length and a width of a sliding time window are set. Data interception on the first voltage data matrix A is performed by using the sliding time window to form a second voltage data matrix B.

(S102) Voltage values of the second voltage data matrix B is subjected to data exclusion and reconstruction based on a data processing method to form a third voltage data matrix D.

(S103) A Shannon entropy value of each of the plurality of cells is calculated based on the third voltage data matrix D by using an optimized entropy algorithm;.

(S104) The Shannon entropy value is transformed into a voltage abnormal fluctuation evaluation coefficient based on an improved Z-score method.

(S105) Whether there is an abnormal cell among the plurality of cells is determined based on a safety evaluation strategy. If yes, step (S106) is proceeded; otherwise, step (S107) is proceeded.

(S106) A position and an occurrence time of the abnormal cell are determined. An abnormality degree of the abnormal cell is determined to send a corresponding alert to a driver.

(S107) The sliding time window down is moved down within the first voltage data matrix A. Steps (S101)-(S105) are repeated for a next iteration.

It will be understood by those skilled in the art that embodiments of the present disclosure may be provided as a method, system, or computer program product. Therefore, the present disclosure may be implemented entirely in hardware, entirely in software, or in a combination of both hardware and software. Moreover, the present disclosure may be implemented in the form of a computer program product stored on one or more computer-readable storage medium containing computer-usable program code, including but not limited to magnetic disk storage, CD-ROM, optical storage, and so forth.

The present disclosure is described with reference to flowcharts and/or block diagrams of methods, devices (systems), and computer program products according to embodiments of the disclosure. It should be understood that each block and/or combination of blocks in the flowcharts and/or block diagrams can be implemented by computer program instructions. These computer program instructions may be provided to a general-purpose computer, special-purpose computer, embedded processor, or other programmable data processing device to produce a machine, which, when the instructions are executed by the computer or other programmable data processing device, creates means for implementing the functions specified in one or more blocks of the flowcharts and/or block diagrams.

These computer program instructions may also be stored in a computer-readable storage medium that can direct a computer or other programmable data processing device to operate in a specific manner, such that the instructions stored in the computer-readable storage medium constitute an article of manufacture including instruction means, which implement the functions specified in one or more blocks of the flowcharts and/or block diagrams.

Additionally, these computer program instructions may be loaded onto a computer or other programmable data processing device to cause a series of operational steps to be performed on the computer or other programmable device to produce a computer-implemented process such that the instructions executed on the computer or other programmable device provide steps for implementing the functions specified in one or more blocks of the flowcharts and/or block diagrams.

It is apparent that those skilled in the art may make various modifications and adaptations to the present disclosure without departing from the spirit and scope of the disclosure. Therefore, if these modifications and adaptations fall within the scope of the claims of the present disclosure and their equivalent technologies, the present disclosure is intended to include these modifications and adaptations.

What is claimed is:

1. A method for online diagnosis of power battery voltage fault based on an entropy algorithm, comprising:
(S100) obtaining a voltage time-series data of each of a plurality of cells in a battery pack of a to-be-diagnosed vehicle to construct a first voltage data matrix A;
wherein the first voltage data matrix A is expressed by:
$$A = [ \begin{matrix}{a}_{1 , 1} & {a}_{1 , 2} & ⋯ & {a}_{1 , n} \\ {a}_{2 , 1} & {a}_{2 , 2} & ⋯ & {a}_{2 , n} \\ ⋮ & ⋮ & {a}_{i , j} & ⋮ \\ {a}_{m , 1} & {a}_{m , 2} & ⋯ & {a}_{m , n}\end{matrix} ] ;$$
wherein m is a time-series length; n is the number of the plurality of cells; and a_{i,j} represents a voltage of a j-th cell at an i-th index; i=1, 2, . . . m; and j=1, 2, . . . n;
(S101) setting a length and a width of a sliding time window; and performing data interception on the first voltage data matrix A by using the sliding time window to form a second voltage data matrix B;
(S102) subjecting voltage values of the second voltage data matrix B to data exclusion and reconstruction based on a data processing method to form a third voltage data matrix D;
(S103) calculating a Shannon entropy value of each of the plurality of cells based on the third voltage data matrix D by using an optimized entropy algorithm;
(S104) transforming the Shannon entropy value into a voltage abnormal fluctuation evaluation coefficient based on an improved Z-score method;
(S105) determining whether there is an abnormal cell among the plurality of cells based on a safety evaluation strategy; if yes, proceeding to step (S106); otherwise, proceeding to step (S107);
(S106) determining a position and an occurrence time of the abnormal cell; and determining an abnormality degree of the abnormal cell to send a corresponding alert to a driver; and
(S107) moving the sliding time window down within the first voltage data matrix A, and repeating steps (S101)-(S105) for a next iteration.

2. The method of claim 1, wherein the length of the sliding time window is k, and the width of the sliding time window is equal to the number of the plurality of cells n; and the second voltage data matrix B is represented by:
$$B = [ \begin{matrix}{b}_{1 , 1} & {b}_{1 , 2} & ⋯ & {b}_{1 , n} \\ {b}_{2 , 1} & {b}_{2 , 2} & ⋯ & {b}_{2 , n} \\ ⋮ & ⋮ & {b}_{i , j} & ⋮ \\ {b}_{k , 1} & {b}_{k , 2} & ⋯ & {b}_{k , n}\end{matrix} ] ;$$
wherein b_{i,j} represents the voltage value of the j-th cell at the i-th index; i=1, 2, . . . k; and j=1, 2, . . . n.

3. The method of claim 2, wherein the step (S102) comprises:
(S200) monitoring a voltage difference between neighboring data sampling points for each of the plurality of cells to establish a voltage difference matrix C; wherein the voltage difference matrix C is represented by:
$$C = [ \begin{matrix}{c}_{1 , 1} & {c}_{1 , 2} & ⋯ & {c}_{1 , n} \\ {c}_{2 , 1} & {c}_{2 , 2} & ⋯ & {c}_{2 , n} \\ ⋮ & ⋮ & {c}_{i , j} & ⋮ \\ {c}_{k - 1 , 1} & {c}_{k - 1 , 2} & ⋯ & {c}_{k - 1 , n}\end{matrix} ] ;$$
wherein c_{i,j} represents a voltage difference of the j-th cell between the i-th index and an (i+1)-th index; i=1, 2, . . . , k−1; and j=1, 2, . . . , n;
(S201) for each of the plurality of cells, identifying data locations in the voltage difference matrix C where voltage differences are not greater than 0.001V, and locking row indices for more than k/10 consecutive data points;
(S202) removing data fragments corresponding to the row indices identified in step (S201) from the second voltage data matrix B; and
(S203) sequentially splicing remaining data in the second voltage data matrix B to form the third voltage data matrix D, wherein a value of a spliced point is an average of values of an immediately preceding row and an immediately following row;
the third voltage data matrix D is represented by:
$$D = [ \begin{matrix}{d}_{1 , 1} & {d}_{1 , 2} & ⋯ & {d}_{1 , n} \\ {d}_{2 , 1} & {d}_{2 , 2} & ⋯ & {d}_{2 , n} \\ ⋮ & ⋮ & {d}_{i , j} & ⋮ \\ {d}_{e , 1} & {d}_{e , 2} & ⋯ & {d}_{e , n}\end{matrix} ] ;$$
wherein d_{i,j} represents a voltage of the j-th cell at the i-th index, and e≤k.

4. The method of claim 3, wherein the step (S103) comprises:
(S300) finding a maximum value dₘₐₓ and a minimum value dₘᵢₙ of the third voltage data matrix D; wherein the maximum value dₘₐₓ and the minimum value dₘᵢₙ are represented by:
$$\{ \begin{matrix}{d}_{min} = min \{ {d}_{i , j} \vert i = 1 , 2 , ⋯ , e ; j = 1 , 2 , ⋯ , n \} \\ {d}_{max} = max \{ {d}_{i , j} \vert i = 1 , 2 , ⋯ , e ; j = 1 , 2 , ⋯ , n \}\end{matrix} ;$$
(S301) dividing a range formed by the maximum value dₘₐₓ and the minimum value dₘᵢₙ into/intervals, each represented by:
$$( {d}_{min} + ( L - 1 ) \frac{{d}_{max} - {d}_{min}}{l} , {d}_{min} + L \frac{{d}_{max} - {d}_{min}}{l} ) ;$$
wherein L=1, 2, 3, . . . 1;
(S302) calculating the number of voltage values of each of the plurality of cells in the third voltage data matrix D respectively falling into each of the/intervals to obtain a frequency matrix F, represented by:
$$F = [ \begin{matrix}{f}_{1 , 1} & {f}_{1 , 2} & ⋯ & {f}_{1 , n} \\ {f}_{2 , 1} & {f}_{2 , 2} & ⋯ & {f}_{2 , n} \\ ⋮ & ⋮ & {f}_{i , j} & ⋮ \\ {f}_{l , 1} & {f}_{l , 2} & ⋯ & {f}_{l , n}\end{matrix} ] ;$$
wherein f_{i,j} represents the number of voltage values of the j-th cell in the third voltage data matrix D that falls into an i-th interval;
(S303) dividing each value in the frequency matrix F by a sum of values in a corresponding column of the frequency matrix F to obtain a probability matrix P, represented by:
$$P = [ \begin{matrix}{p}_{1 , 1} & {p}_{1 , 2} & ⋯ & {p}_{1 , n} \\ {p}_{2 , 1} & {p}_{2 , 2} & ⋯ & {p}_{2 , n} \\ ⋮ & ⋮ & {p}_{i , j} & ⋮ \\ {p}_{l , 1} & {p}_{l , 2} & ⋯ & {p}_{l , n}\end{matrix} ] ;$$
wherein
$${p}_{i , j} = \frac{{f}_{i , j}}{{\sum }_{i = 1}^{l} {f}_{i , j}} ,$$
representing a probability that the voltage values of the j-th cell in the third voltage data matrix D fall into the i-th interval; and
(S304) calculating the Shannon entropy value of each of the plurality of cells based on the second voltage data matrix B to obtain a first Shannon entropy sequence H(B); wherein the first Shannon entropy sequence H(B) is expressed by:
$$H ( B ) = [ {H}_{1} , {H}_{2} , ⋯ , {H}_{j} , ⋯ , {H}_{n} ] ;$$
$$wherein$$
$${H}_{j} = - {\sum }_{i = 1}^{l} {p}_{i , j} log {p}_{i , j} ,$$
representing a Shannon entropy value of the j-th cell calculated based on the second voltage data matrix B.

5. The method of claim 4, wherein the step (S104) comprises:
(S400) obtaining the first Shannon entropy sequence H(B);
(S401) calculating a mean value μ_{H} of Shannon entropy values of the plurality of cells in the first Shannon entropy sequence;
(S402) excluding values exceeding 2*μ_{H} from the first Shannon entropy sequence H(B) to form a second Shannon entropy sequence H(B)′; and
calculating a mean value and a standard deviation of Shannon entropy values in the second Shannon entropy sequence H(B) respectively according to the following equations:
$${μ}_{{H}^{′}} = \frac{1}{g} {\sum }_{j = 1}^{g} {H}_{j} ;$$
$$and$$
$${σ}_{{H}^{′}} = \sqrt{\frac{1}{g} {\sum }_{j = 1}^{g} {( {H}_{j} - {μ}_{{H}^{′}} )}^{2}} ;$$
(S403) calculating a median Hₘₑ of the Shannon entropy values of the plurality of cells in the second Shannon entropy sequence; and
(S404) normalizing the Shannon entropy values of the plurality of cells in the second Shannon entropy sequence H(B)′ to obtain the voltage abnormal fluctuation evaluation coefficient of the plurality of cells, expressed by:
$${AF}_{j} = \frac{{H}_{j}^{′} - {H}_{me}}{{σ}_{{H}^{′}}} ;$$
wherein Hⱼ′ represents a Shannon entropy value of the j-th cell in the second Shannon entropy sequence; and σ_{H}′ represents the standard deviation of the second Shannon entropy sequence.

6. The method of claim 5, wherein the safety evaluation strategy is performed through steps of:
(S500) determining whether there is a cell among the plurality of cells whose voltage abnormal fluctuation evaluation coefficient absolute value is greater than 3.5, wherein the cell whose voltage abnormal fluctuation evaluation coefficient absolute value is greater than 3.5 is identified as the abnormal cell;
(S501) if not, proceeding to step (S502); and if yes, proceeding to step (S503);
(S502) moving the sliding time window down by one row within the first voltage data matrix A and repeating steps (S101)-(S105) for the next iteration;
(S503) determining whether the voltage abnormal fluctuation evaluation coefficient absolute value is larger than 4; if yes, proceeding to step (S505), otherwise, proceeding to step (S504);
(S504) sending a secondary fault warning; calculating a duration of a secondary fault; determining whether the duration of the secondary fault exceeds a preset threshold;
if yes, proceeding to step (S505), otherwise, returning to step (S502);
(S505) sending a primary fault warning to the driver, and checking the to-be-diagnosed vehicle.

7. A device for online diagnosis of power battery voltage fault based on the entropy algorithm, comprising:
a memory configured to store a computer program; and
a processor;
wherein the processor is configured to execute the computer program to implement the method of claim 1.

8. A non-transitory computer-readable storage medium, wherein the non-transitory computer-readable storage medium stores a computer program; and the computer program is configured to be executed by a processor to implement the method of claim 1.
